(19) United States
(12) Patent Application Publication
(10) Pub. No.: US 2025/0151477 A1
(43) Pub. Date: May 8, 2025

(54) DISPLAY DEVICE, METHOD OF MANUFACTURING THE SAME, AND ELECTRONIC DEVICE

(71) Applicant: Samsung Display Co., LTD., Yongin-si (KR)

(72) Inventor: YOONHO KANG, Yongin-si (KR)

(73) Assignee: Samsung Display Co., LTD., Yongin-si (KR)

(21) Appl. No.: 18/937,650

(22) Filed: Nov. 5, 2024

(30) Foreign Application Priority Data
Nov. 6, 2023 (KR) 10-2023-0152210

(51) Int. Cl. H01L 33/46; H01L 25/075; H01L 33/00; H01L 33/06

(52) U.S. Cl. CPC H10H 20/841; H10H 20/01; H10H 20/812; H01L 25/0753; H10H 20/034

(57) ABSTRACT

A display device includes a first electrode, a second electrode on the first electrode and facing the first electrode, an intermediate layer between the first electrode and the second electrode and including an emission layer including a quantum dot, a first pixel defining layer which covers at least a portion of the first electrode and exposes an upper surface of the first electrode, a reflective film on the first pixel defining layer, and a second pixel defining layer on the reflective film.

### CROSS-REFERENCE TO RELATED APPLICATION

This application claims priority to Korean Patent Application No. 10-2023-0152210, filed on Nov. 6, 2023, and all the benefits accruing therefrom under 35 U.S.C. § 119, the content of which in its entirety is herein incorporated by reference.

### BACKGROUND

### 1. Technical Field

The disclosure relates to a display device. More specifically, the disclosure relates to a display device including quantum dot and a method of manufacturing the display device.

### 2. Description of the Related Art

As information technology develops, the importance of a display device as a connection medium between a user and information is being highlighted. For example, the use of display devices such as the like a liquid crystal display device (LCD), an organic light emitting display device (OLED), a plasma display device (PDP), a quantum dot display device is increasing.

The quantum dot display device includes a quantum dot light emitting element, and the quantum dot light emitting element has an advantage of high chromaticity, high luminous efficiency, and multi-coloring.

### SUMMARY

Embodiments provide a display device with improved element characteristics.

Embodiments provide a method for manufacturing the display device.

Embodiments provide an electronic device including the display device.

A display device according to an embodiment includes a first electrode, a second electrode on the first electrode and facing the first electrode, an intermediate layer between the first electrode and the second electrode and including an emission layer including a quantum dot, a first pixel defining layer which covers at least a portion of the first electrode and exposes an upper surface of the first electrode, a reflective film on the first pixel defining layer, and a second pixel defining layer on the reflective film.

In an embodiment, the reflective film may include a metal material.

In an embodiment, the reflective film may include aluminum or an aluminum alloy.

In an embodiment, the reflective film may be electrically disconnected from the first electrode.

In an embodiment, the emission layer may further include a cross-linking agent activated by ultraviolet rays.

In an embodiment, a structure in which the first pixel defining layer, the reflective film, and the second pixel defining layer are sequentially stacked may define a pixel opening exposing the upper surface of the first electrode, and the intermediate layer may be disposed in the pixel opening.

In an embodiment, a structure in which the first pixel defining layer, the reflective film, and the second pixel defining layer are sequentially stacked may surround the intermediate layer in a plan view.

In an embodiment, the intermediate layer may further include a metal oxide layer adjacent to the emission layer and including metal oxide.

In an embodiment, the reflective film may directly contact the intermediate layer.

In an embodiment, at least a portion of the reflective film may be exposed from the second pixel defining layer.

In an embodiment, the second pixel defining layer may include a light blocking material.

A method of manufacturing a display device according to an embodiment includes forming a first pixel defining layer which covers at least a portion of a first electrode and exposes an upper surface of the first electrode, forming a reflective film on the first pixel defining layer, forming a second pixel defining layer on the reflective film, forming an emission layer including a quantum dot on the first electrode, and curing the emission layer with ultraviolet rays.

In an embodiment, the emission layer may further include a cross-linking agent activated by the ultraviolet rays.

In an embodiment, in the curing of the emission layer with the ultraviolet rays, at least some of the ultraviolet rays may be reflected by the reflective film and reach the emission layer.

In an embodiment, the curing of the emission layer with the ultraviolet rays may be performed at a temperature of less than about 180° C.

In an embodiment, the forming of the reflective film may include the forming a preliminary reflective film including a metal material on the first electrode and the first pixel defining layer and patterning the preliminary reflective film.

In an embodiment, the preliminary reflective film may include aluminum or an aluminum alloy.

In an embodiment, the method may further include forming a metal oxide layer including metal oxide on the first electrode and radiating ultraviolet rays to the metal oxide layer.

In an embodiment, in the radiating of the ultraviolet rays to the metal oxide layer, at least some of the ultraviolet rays may be reflected by the reflective film and reach the metal oxide layer.

In an embodiment, the emission layer and the metal oxide layer may be formed adjacent to each other.

An electronic device according to an embodiment includes a display device and a power supply which provides power to the display device. The display device includes a first electrode, a second electrode on the first electrode and facing the first electrode, an intermediate layer between the first electrode and the second electrode and including an emission layer including a quantum dot, a first pixel defining layer which covers at least a portion of the first electrode and exposes an upper surface of the first electrode, a reflective film on the first pixel defining layer, and a second pixel defining layer on the reflective film.

The display device according to embodiments may include the first pixel defining layer covering at least a portion of the first electrode of the light emitting element, the reflective film on the first pixel defining layer, and the second pixel defining layer on the reflective film. For example, in the display device according to embodiments, the structure in which the first pixel defining layer, the reflective film, and the second pixel defining layer are sequentially stacked may define the pixel opening which exposes the upper surface of the first electrode of the light emitting element.

Additionally, in the method of manufacturing the display device according to embodiments, the emission layer included in the light emitting element may be cured with the ultraviolet rays, and the surface of the metal oxide layer included in the light emitting element may be modified by radiating the ultraviolet rays to the metal oxide layer.

Accordingly, in a process of curing the emission layer formed in the pixel opening with the ultraviolet rays, at least some of the ultraviolet rays which is radiated may be reflected by the reflective film and reach the emission layer. For example, in addition to the ultraviolet rays that directly reach the emission layer, the ultraviolet rays reflected by the reflective film may additionally reach the emission layer. Accordingly, an amount of the ultraviolet rays reaching the emission layer may increase, and a degree of film curing of the emission layer by radiating the ultraviolet rays may increase. Accordingly, a phenomenon in which materials included in the emission layer and materials included in the metal oxide layer are mixed at the interface between the emission layer and the metal oxide layer may be further reduced or prevented. Accordingly, element characteristics of the light emitting element may be improved.

Additionally, in a process of modifying the surface of the metal oxide layer by radiating the ultraviolet rays to the metal oxide layer formed in the pixel opening, at least some of the ultraviolet rays which is radiated may be reflected by the reflective film and reach the metal oxide layer. For example, in addition to the ultraviolet rays that directly reach the metal oxide layer, the ultraviolet rays reflected by the reflective film may additionally reach the metal oxide layer. Accordingly, an amount of the ultraviolet rays reaching the metal oxide layer may increase, and a surface modification effect of the metal oxide layer by radiating the ultraviolet rays may increase. Accordingly, element characteristics of the light emitting element may be improved.

It is to be understood that both the foregoing general description and the following detailed description are explanatory and are intended to provide further explanation of the invention as claimed.

### BRIEF DESCRIPTION OF THE DRAWINGS

Illustrative, non-limiting embodiments will be more clearly understood from the following detailed description taken in conjunction with the accompanying drawings.

FIG. 1 is a schematic plan view illustrating a display device according to an embodiment of the disclosure.

FIG. 2 is a schematic cross-sectional view taken along line I-I′ of FIG. 1.

FIGS. 3 to 13 are schematic cross-sectional views illustrating a method of manufacturing a display device according to an embodiment of the disclosure.

FIGS. 14 to 17 are schematic cross-sectional views illustrating various embodiments taken along line I-I′ of FIG. 1.

FIG. 18 is a block diagram illustrating an electronic device according to an embodiment of the disclosure.

FIG. 19 is a view illustrating an example in which the electronic device of FIG. 18 is implemented as a smart phone.

### DETAILED DESCRIPTION OF THE EMBODIMENTS

Hereinafter, display devices in accordance with embodiments will be described in more detail with reference to the accompanying drawings. The same reference numerals are used for the same components in the drawings, and redundant descriptions of the same components will be omitted.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

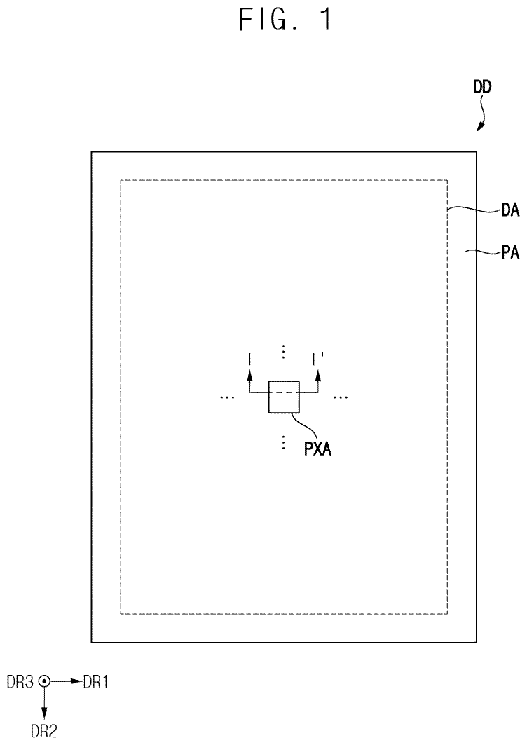

FIG. 1 is a schematic plan view illustrating a display device DD according to an embodiment of the disclosure.

Referring to FIG. 1, the display device DD according to an embodiment of the disclosure may include a display area DA and a peripheral area PA. The display area DA may be an area that can display an image by generating light or adjusting a transmittance of light provided from an external light source. The peripheral area PA may be an area that does not display images. The peripheral area PA may be located around the display area DA. For example, the peripheral area PA may entirely surround the display area DA.

The display area DA may include pixel areas PXA. The pixel areas PXA may be arranged in a matrix form on a plane defined by a first direction DR1 and a second direction DR2 intersecting the first direction DR1.

The third direction DR3 may be a normal direction of the plane defined by the first direction DR1 and the second direction DR2. For example, the third direction DR3 may be perpendicular to the first direction DR1 and the second direction DR2.

The pixel areas PXA may refer to areas where light emitted from a light emitting element is emitted to the outside of the display device DD. Each of the pixel areas PXA may have a triangular planar shape, a square planar shape, a circular planar shape, an oval planar shape, or the like. In an embodiment, each of the pixel areas PXA may have a rectangular planar shape. However, the disclosure is not limited thereto, and each of the pixel areas PXA may have a planar shape other than a rectangular planar shape.

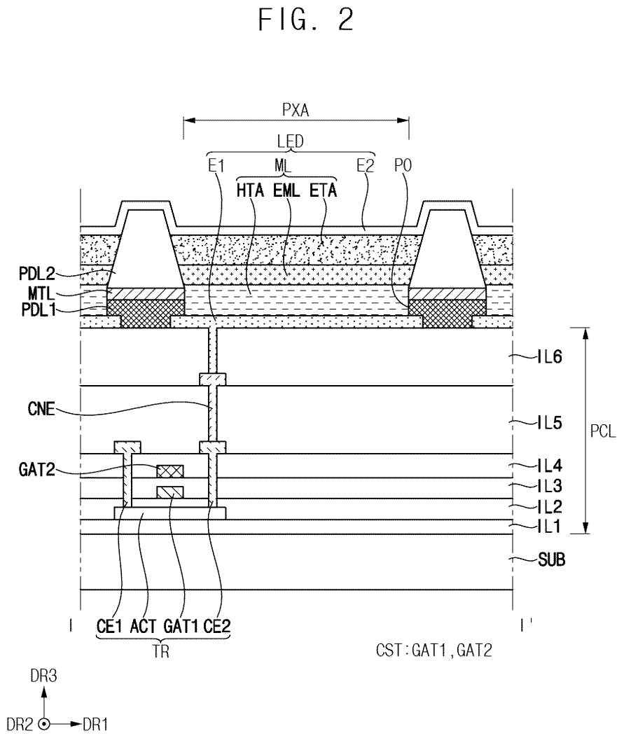

FIG. 2 is a schematic cross-sectional view taken along line I-I′ of FIG. 1.

Specifically, FIG. 2 is a schematic cross-sectional view illustrating one pixel area among the pixel areas PXA of FIG. 1.

Referring to FIGS. 1 and 2, the display device DD may include a substrate SUB, a pixel circuit layer PCL, a light emitting element LED, a first pixel defining layer PDL1, a reflective film MTL, and a second pixel defining layer PDL2.

The substrate SUB may include, e.g., a transparent, semi-transparent, and/or opaque material. In an embodiment, examples of materials that can be used as the substrate SUB may include glass, quartz, plastic, or the like. These can be used alone or in combination with each other.

The pixel circuit layer PCL may be disposed on the substrate SUB. The pixel circuit layer PCL may include first to sixth insulating layers IL1, IL2, IL3, IL4, IL5, and IL6, at least one transistor TR, at least one capacitor CST, and at least one connection electrode CNE.

The transistor TR may include an active pattern ACT, a first gate electrode GAT1, a first contact electrode CE1, and a second contact electrode CE2. The capacitor CST may include the first gate electrode GAT1 and the second gate electrode GAT2. The light emitting element LED may include a first electrode E1, an intermediate layer ML, and a second electrode E2. The intermediate layer ML may include a hole transport area HTA, an emission layer EML, and an electron transport area ETA.

The first insulating layer IL1 may be disposed on the substrate SUB. The first insulating layer IL1 may prevent impurities such as oxygen and moisture from diffusing into an upper part of the substrate SUB. The first insulating layer IL1 may include an inorganic insulating material such as a silicon compound or metal oxide.

The active pattern ACT may be disposed on the first insulating layer IL1. In an embodiment, the active pattern ACT may include a silicon semiconductor material or an oxide semiconductor material.

In an embodiment, the second insulating layer IL2 may be disposed on the first insulating layer IL1. The second insulating layer IL2 may cover (or overlap) the active pattern ACT. In an embodiment, the second insulating layer IL2 may be arranged in a pattern form on the active pattern ACT to expose a portion of the active pattern ACT. For example, the second insulating layer IL2 may be disposed in a pattern form on the active pattern ACT so as to overlap the first gate electrode GAT1. The second insulating layer IL2 may include an inorganic insulating material.

The first gate electrode GAT1 may be disposed on the second insulating layer IL2. In an embodiment, the first gate electrode GAT1 may include metal, alloy, conductive metal oxide, transparent conductive material, or the like.

The third insulating layer IL3 may be disposed on the second insulating layer IL2. In an embodiment, the third insulating layer IL3 may cover the first gate electrode GAT1. The third insulating layer IL3 may include an inorganic insulating material.

The second gate electrode GAT2 may be disposed on the third insulating layer IL3. In an embodiment, the second gate electrode GAT2 may overlap the first gate electrode GAT1. In an embodiment, the second gate electrode GAT2 may include metal, alloy, conductive metal oxide, transparent conductive material, or the like. The first gate electrode GAT1 and the second gate electrode GAT2 may form the capacitor CST.

The fourth insulating layer IL4 may be disposed on the third insulating layer IL3. In an embodiment, the fourth insulating layer IL4 may cover the second gate electrode GAT2. The fourth insulating layer IL4 may include an inorganic insulating material.

The first contact electrode CE and the second contact electrode CE2 may be disposed on the fourth insulating layer IL4. The first contact electrode CE1 and the second contact electrode CE2 may be electrically connected to the active pattern ACT through contact holes formed in the second to fourth insulating layers IL2, IL3, IL4. For example, the first contact electrode CE1 and the second contact electrode CE2 may contact the active pattern ACT. Each of the first contact electrode CE1 and the second contact electrode CE2 may include metal, alloy, conductive metal oxide, transparent conductive material, or the like.

The fifth insulating layer IL5 may be disposed on the fourth insulating layer IL4. The fifth insulating layer IL5 may cover the first contact electrode CE1 and the second contact electrode CE2. The fifth insulating layer IL5 may include an organic insulating material.

The connection electrode CNE may be disposed on the fifth insulating layer IL5. The connection electrode CNE may be electrically connected to at least one of the first contact electrode CE1 and the second contact electrode CE2 through a contact hole formed in the fifth insulating layer IL5. The connection electrode CNE may include metal, alloy, conductive metal oxide, transparent conductive material, or the like.

The sixth insulating layer IL6 may be disposed on the fifth insulating layer IL5. The sixth insulating layer IL6 may cover the connection electrode CNE. The sixth insulating layer IL6 may include an organic insulating material.

A structure of the pixel circuit layer PCL illustrated in FIG. 2 is merely an example and may be changed in various ways depending on embodiments.

The first electrode E1 may be disposed on the sixth insulating layer IL6. The first electrode E1 may be electrically connected to the connection electrode CNE through a contact hole formed in the sixth insulating layer IL6. For example, the first electrode E1 may be electrically connected to the transistor TR through the connection electrode CNE. The first electrode E1 may include metal, alloy, conductive metal oxide, transparent conductive material, or the like.

The first pixel defining layer PDL1 may be disposed on the sixth insulating layer IL6. For example, the first pixel defining layer PDL1 and the first electrode E1 may be disposed at a same level from the substrate SUB. The first pixel defining layer PDL1 may cover at least a portion of the first electrode E1 and expose another portion of the first electrode E1. Specifically, the first pixel defining layer PDL1 may expose an upper surface of the first electrode E1. For example, the first pixel defining layer PDL1 may cover an edge of the first electrode E1 and expose a central portion of the first electrode E1. However, the disclosure is not limited thereto.

In an embodiment, the first pixel defining layer PDL1 may include an organic material. Examples of the organic material that can be used as the first pixel defining layer PDL1 may include photoresist, polyacrylic resin, polyimide resin, acrylic resin, or the like. These can be used alone or in combination with each other. For example, the first pixel defining layer PDL1 may have a grid shape in a plan view.

In an embodiment, a thickness of the first pixel defining layer PDL1 in the third direction DR3 may be in a range of about 500 Å to about 2000 Å, e.g., in a range of about 1000 Å to about 2000 Å. In case that the thickness of the first pixel defining layer PDL1 satisfies the above-described range, the reflective film MTL and the first electrode E1 may be electrically insulated from each other without substantially increasing a thickness of the display device DD in the third direction DR3.

The reflective film MTL may be disposed on the first pixel defining layer PDL1. For example, the reflective film MTL may have a grid shape in a plan view.

In an embodiment, the reflective film MTL may include a metal material. For example, the metal material included in the reflective film MTL may have a low resistance and a high reflectivity. For example, the reflective film MTL may include aluminum (Al) or an aluminum alloy. The aluminum alloy may include metals such as nickel (Ni), lanthanum (La), titanium (Ti), molybdenum (Mo), or the like., but the disclosure is not limited thereto.

In an embodiment, a thickness of the reflective film MTL in the third direction DR3 may be in a range of about 50 Å to about 2000 Å, e.g., in a range of about 500 Å to about 1000 Å. In case that the thickness of the reflective film MTL satisfies the above-described range, in a process of radiating ultraviolet rays described below, an amount of the ultraviolet rays radiated to the intermediate layer ML (e.g., emission layer EML) may be more effectively increased. For example, the thickness of the reflective film MTL may be about 1000 Å.

In an embodiment, the reflective film MTL may be electrically insulated from the first electrode E1. For example, the reflective film MTL may not contact the first electrode E1. Specifically, the reflective film MTL may be disposed on the first pixel defining layer PDL1 and be electrically insulated from the first electrode E1 by the first pixel defining layer PDL1. Accordingly, the reflective film MTL may not affect electrical characteristics of the light emitting element LED.

In an embodiment, the reflective film MTL may entirely cover an upper surface of the first pixel defining layer PDL1. However, the disclosure is not limited thereto. In FIG. 2, the reflective film MTL is illustrated as not being disposed on a side surface of the first pixel defining layer PDL1, but the disclosure is not limited thereto. For example, the reflective film MTL may also cover (or overlap) a portion of the side surface of the first pixel defining layer PDL1.

The second pixel defining layer PDL2 may be disposed on the reflective film MTL. The second pixel defining layer PDL2 may include, e.g., an organic insulating material. Examples of the organic insulating material that can be used as the second pixel defining layer PDL2 may include photoresist, polyacrylic resin, polyimide resin, acrylic resin, or the like. These can be used alone or in combination with each other. For example, the second pixel defining layer PDL2 may have a grid shape in a plan view.

Consequently, a structure in which the first pixel defining layer PDL1, the reflective film MTL, and the second pixel defining layer PDL2 are sequentially stacked may define a pixel opening PO exposing the upper surface of the first electrode E1. For example, the structure in which the first pixel defining layer PDL1, the reflective film MTL, and the second pixel defining layer PDL2 are sequentially stacked may have a grid shape in a plan view.

In an embodiment, the second pixel defining layer PDL2 may have a liquid repellency. Specifically, an upper surface of the second pixel defining layer PDL2 may have a liquid repellency. In this specification, a liquid repellency may mean a property of repelling a solution (e.g., a predetermined or selectable solution) and preventing the solution from permeating well. For example, a surface bonding force of the solution with a surface having a liquid repellency may be relatively small, and a surface tension of the solution disposed on the surface having a liquid repellency may increase.

As the second pixel defining layer PDL2 may have a liquid repellency, in a process of forming the intermediate layer ML in the pixel opening PO, a phenomenon in which materials discharged into the pixel opening PO through inkjet printing overflow onto the upper surface of the second pixel defining layer PDL2 may be reduced or prevented. Accordingly, defects in a manufacturing process of the display device DD may be reduced or prevented.

The second pixel defining layer PDL2 may expose at least a portion of the reflective film MTL. Accordingly, the reflective film MTL may directly contact the intermediate layer ML in the pixel opening PO. For example, the second pixel defining layer PDL2 may expose at least a portion of a side surface of the reflective film MTL, and the side surface of the reflective film MTL may directly contact the intermediate layer ML.

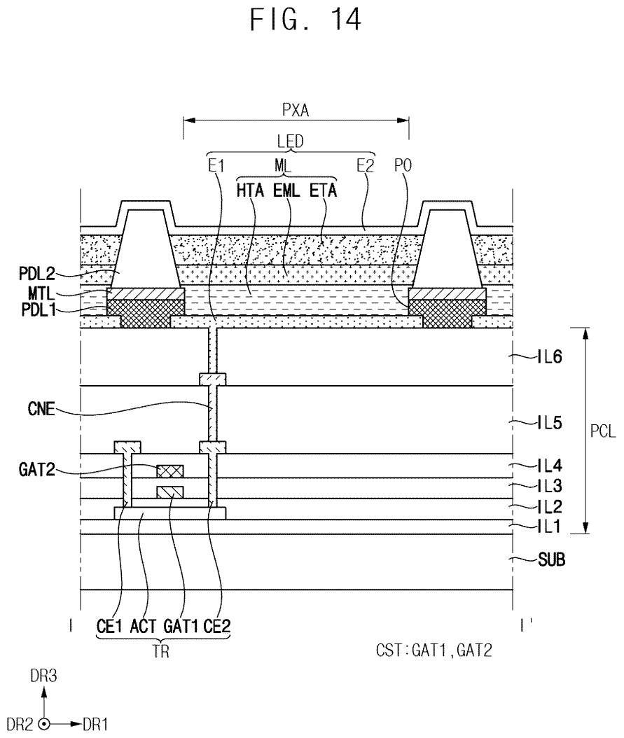

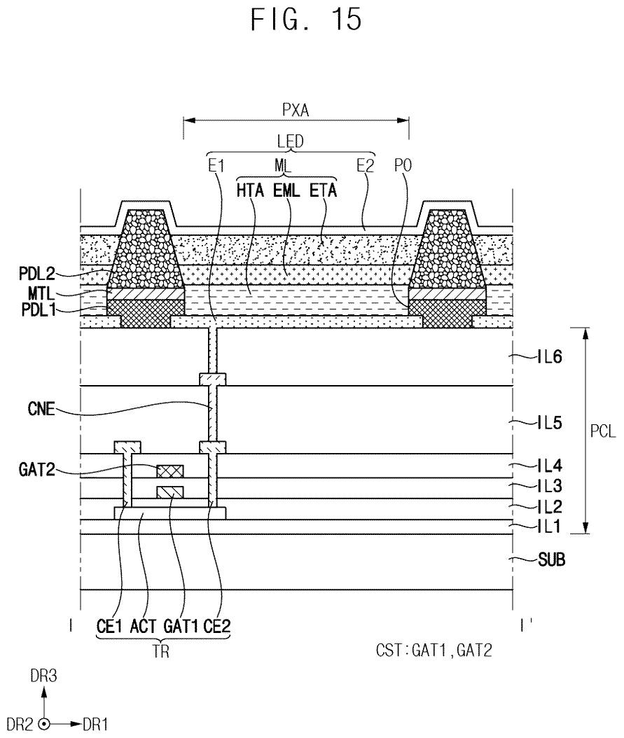

In an embodiment, the second pixel defining layer PDL2 may entirely cover (or overlap) an upper surface of the reflective film MTL. However, the disclosure is not limited thereto, and the second pixel defining layer PDL2 may also expose at least a portion of the upper surface of the reflective film MTL. This will be described in more detail below with reference to FIG. 14.

In FIG. 2, the second pixel defining layer PDL2 is illustrated as not being disposed on the side surface of the reflective film MTL, but the disclosure is not limited thereto, and the second pixel defining layer PDL2 may also cover a portion of the side surface of the reflective film MTL. For example, the second pixel defining layer PDL2 may expose a portion of the side surface of the reflective film MTL and cover another portion of the side surface of the reflective film MTL.

The intermediate layer ML may be disposed in the pixel opening PO. For example, the intermediate layer ML may be disposed on the first electrode E1. In an embodiment, the intermediate layer ML may include a material that emits light.

For example, the structure in which the first pixel defining layer PDL1, the reflective film MTL, and the second pixel defining layer PDL2 are sequentially stacked may surround the intermediate layer ML in a plan view. Specifically, the first pixel defining layer PDL1 may surround the intermediate layer ML in a plan view, the reflective film MTL may surround the intermediate layer ML in a plan view, and the second pixel defining layer PDL2 may surround the intermediate layer ML in a plan view.

As described above, the intermediate layer ML may include the hole transport area HTA, the emission layer EML, and the electron transport area ETA. In an embodiment, the hole transport area HTA, the emission layer EML, and the electron transport area ETA may be sequentially stacked on the first electrode E1. The light emitting element LED may be a normal-structure light emitting element in which the first electrode E1 is an anode and the second electrode E2 is a cathode.

The hole transport area HTA may have i) a single-layer structure formed as a single layer of a single material, ii) a single-layer structure formed as a single layer of different materials, or iii) a multi-layer structure having layers of different materials.

The hole transport area HTA may include at least one layer of a hole injection layer, a hole transport layer, a light emission auxiliary layer, and an electron blocking layer.

For example, the hole transport area HTA may have a single-layer structure formed as a single layer of different materials, or a multi-layer structure of a hole injection layer/hole transport layer, a hole injection layer/hole transport layer/light emission auxiliary layer, a hole injection layer/light emission auxiliary layer, a hole transport layer/light emission auxiliary layer, or a hole injection layer/hole transport layer/electron blocking layer sequentially stacked on the first electrode E1. However, the disclosure is not limited thereto.

The hole transport area HTA may include an amorphous inorganic or organic material. A thickness of the hole transport area HTA may be in a range of about 100 Å to about 10,000 Å, for example, e.g., in a range of about 100 Å to about 1,000 Å. If the hole transport area HTA includes at least one of the hole injection layer and the hole transport layer, a thickness of the hole injection layer may be in a range of about 100 Å to about 9,000 Å, e.g., in a range of about 100 Å to about 1000 Å, and a thickness of the hole transport layer may be in a range of about 50 Å to about 2000 Å, e.g., in a range of about 100 Å to about 1500 Å. In case that the thicknesses of the hole transport area HTA, the thickness of the hole injection layer, and the thickness of the hole transport layer satisfy the ranges described above, satisfactory hole transport characteristics may be obtained without a substantial increase in driving voltage.

The emission layer EML may include a material which emits light. For example, the emission layer EML may include a quantum dot. The quantum dot may emit light when stimulated by light. For example, the light emitting element LED may be a quantum dot light emitting element.

For example, the quantum dot may include a group II-VI semiconductor compound, a group III-VI semiconductor compound, a group III-V semiconductor compound, a group IV-VI semiconductor compound, a group IV element or compound, a group I-III-VI semiconductor compound, or the like. These can be used alone or in combination with each other.

Examples of the group II-VI semiconductor compound may include binary compounds such as CdS, CdSe, CdTe, ZnS, ZnSe, ZnTe, ZnO, HgS, HgSe, HgTe, MgS, MgSe, etc.; ternary compounds such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe MgZnS, MgZnSe, etc.; quaternary compounds such as CdZnSeS, CdZnSeTe, CdZnSTe, CdHgSeS, CdHgSeTe, CdHgSTe, HgZnSeS, HgZnSeTe, HgZnSTe, etc.; or any combination thereof.

Examples of the group III-VI semiconductor compound may include binary compounds such as In₂S₃, Ga₂S₃, etc.; ternary compounds such as InGaS₃, InGaSe₃, etc.; or any combination thereof.

Examples of the group III-V semiconductor compound may include binary compounds such as GaN, GaP, GaAs, GaSb, AlN, AlP, AlAs, AlSb, InN, InP, InAs, InSb, etc.; ternary compounds such as GaNP, GaNAs, GaNSb, GaPAs, GaPSb, AlNP, AlNAs, AlNSb, AlPAS, AlPSb, InAsP, InGaP, InGaAs, InAlP, InNP, InNAs, InNSb, InPAs, InPSb, GaAlNP, etc.; quaternary compounds such as GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, etc.; or any combination thereof. The group III-V semiconductor compound may further include a group II metal (e.g., InZnP)

Examples of the group IV-VI semiconductor compound may include binary compounds such as SnS, SnSe, SnTe, PbS, PbSe, PbTe, etc.; ternary compounds such as SnSeS, SnSeTe, SnSTe, PbSeS, PbSeTe, PbSTe, SnPbS, SnPbSe, SnPbTe, etc.; quaternary compounds such as SnPbSSe, SnPbSeTe, SnPbSTe, etc.; or any combination thereof.

Examples of the group IV clement or compound may include Si and/or Ge; binary compounds such as SiC, SiGe, etc.; or any combination thereof.

Examples of the group I-III-VI semiconductor compound may include ternary compounds such as AgInS, AgInS₂, CuInS, CuInS₂, CuGaO₂, AgGaO₂, AgAlO₂, etc.; or any combination thereof. The group I-III-VI semiconductor compound may further include a group Il element. For example, the group I-III-VI semiconductor compound may include a quaternary compound such as CuInZnS.

The quantum dot may have a single structure with homogeneous components and composition, or a complex structure such as a core-shell structure, a gradient structure, or the like.

In an embodiment, the quantum dot may have a core-shell structure including a core including a first semiconductor crystal and a shell including a second semiconductor crystal. The core and the shell may include different materials from each other.

The shell may serve as a protective layer to maintain semiconductor properties by preventing chemical denaturation of the core and/or as a charging layer to impart electrophoretic properties to the quantum dot. The shell may have a single-layer structure or a multi-layer structure. An interface between the core and the shell may have a concentration gradient in which the concentration of elements in the shell decreases toward the center. Examples of the shell of the quantum dot may include oxides of metals or non-metals, semiconductor compounds, or combinations thereof.

For example, in the core-shell structure, each material forming the core and the shell may be selected from the semiconductor compounds described above.

The emission layer EML may include a light-reactive material. For example, the emission layer EML may include a photo-crosslinking agent. Specifically, the emission layer EML may further include a cross-linking agent activated by ultraviolet rays.

Examples of the cross-linking agent that can be included in the emission layer EML may include a crosslinkable monomer having an ethylenically unsaturated group, a urethane monomer, or the like. Examples of the crosslinkable monomer having an ethylenically unsaturated group may include 1,4-butanediol diacrylate, 1,3-butylene glycol diacrylate, ethylene glycol diacrylate, pentaerythritol tetraacrylate, tricthylene glycol diacrylate, polyethylene glycol diacrylate, dipentaerythritol diacrylate, sorbitol triacrylate, bisphenol A diacrylate derivative, trimethylpropanc triacrylate, dipentaerythritol polyacrylate, dipentaerythritol hexaacrylate, or the like. These can be used alone or in combination with each other. The urethane monomer may be a general cross-linking monomer having a urethane structure, and its type is not particularly limited.

The emission layer EML may be formed by applying a composition for forming the emission layer EML in which the quantum dot and the cross-linking agent are dispersed in a solvent onto the first electrode E1 and drying the composition for forming the emission layer EML. A degree of film curing of the emission layer EML may be improved by curing the emission layer EML with ultraviolet rays after drying the composition for forming the emission layer EML. This will be described in more detail below with reference to FIG. 10.

The composition for forming the emission layer EML may be applied using a spin coat method, a casting method, a micro gravure coat method, a gravure coat method, a bar coat method, a roll coat method. a wire bar coat method, a dip coat method, a spray coat method, a screen printing, a flexographic method, an offset printing, an inkjet printing, or the like. The composition for forming the emission layer EML may be applied using the inkjet printing.

The solvent may be water, hexane, chloroform, toluene, or the like, but is not particularly limited as long as dissolving material used to form the emission layer EML.

The electron transport area ETA may have i) a single-layer structure formed of (or formed as) a single layer of a single material, ii) a single-layer structure formed of a single layer of different materials, or iii) a multi-layer structure having layers of different materials.

The electron transport area ETA may include at least one layer of a buffer layer, a hole blocking layer, an electron control layer, an electron transport layer, and an electron injection layer, but the disclosure is not limited thereto.

A thickness of the buffer layer, a thickness of the hole blocking layer, or a thickness of the electron control layer may be independently in a range of about 20 Å to about 1000 Å, e.g., in a range of about 30 Å to about 300 Å. In case that the thickness of the buffer layer, the thickness of the hole blocking layer, or the thickness of the electron control layer satisfies the ranges described above, excellent hole blocking characteristics or electron control characteristics may be obtained without a substantial increase in driving voltage.

The electron transport area ETA may include a metal oxide layer. For example, the metal oxide layer may be at least one layer selected from the buffer layer, the hole blocking layer, the electron control layer, the electron transport layer, and the electron injection layer. In an embodiment, the metal oxide layer may be the electron transport layer. However, the disclosure is not limited thereto.

The metal oxide layer may include a conductive metal oxide, a fullerene derivative, or a combination thereof. For example, the metal oxide layer may include Mg-doped ZnO (ZnMgO), Al-doped ZnO (AZO), Ga-doped ZnO (GZO), In-doped ZnO (IZO), Al-doped SnO₂, Ga-doped SnO₂, In-doped SnO₂, Al-doped TiO₂, Ga-doped TiO₂, In-doped TiO₂, In₂O₃, Nb₂O₅, Fe₂O₃, CeO₂, SrTiO₃, Zn₂SnO₄, BaSnO₃, In₂S₃, ZnSiO, PC60BM, PC70BM, Mg-doped In₂O₃, Al-doped In₂O₃, Ga-doped In₂O₃, Mg-doped Nb₂O₅, Al-doped Nb₂O₅, Ga-doped Nb₂O₅, Mg-doped Fe₂O₃, Al-doped Fe₂O₃, Ga-doped Fe₂O₃, In-doped Fe₂O₃, Mg-doped CeO₂, Al-doped CeO₂, Ga-doped CeO₂, In-doped CeO₂, Mg-doped SrTiO₃, Al-doped SrTiO₃, Ga-doped SrTiO₃, In-doped SrTiO₃, Mg-doped Zn₂SnO₄, Al-doped Zn₂SnO₄, Ga-doped Zn₂SnO₄, In-doped Zn₂SnO₄, Mg-doped BaSnO₃, Al-doped BaSnO₃, Ga-doped BaSnO₃, In-doped BaSnO₃, Mg-doped In₂S₃, Al-doped In₂S₃, Ga-doped In₂S₃, In-doped In₂S₃, Mg-doped ZnSiO, or a combination thereof. Specifically, the metal oxide layer may include zinc-containing oxide. For example, the metal oxide layer may include Mg-doped ZnO (ZnMgO).

In an embodiment, the metal oxide layer may be adjacent to the emission layer EML. For example, the metal oxide layer may form an interface with the emission layer EML. For example, in a normal-structure light emitting element in which the electron transport area ETA is disposed on the emission layer EML, the metal oxide layer may be a lower layer or the lowest layer of the electron transport area ETA. In other words, the metal oxide layer may be disposed on the emission layer EML so as to directly contact the emission layer EML.

Oxygen vacancy may be generated inside the metal oxide layer. If an excessive amount of oxygen vacancy is generated inside the metal oxide layer, electrical properties of the metal oxide layer may change, and thus charge transfer characteristics (e.g., current characteristics) of the metal oxide layer may deteriorate. Accordingly, characteristics of the light emitting element LED may deteriorate.

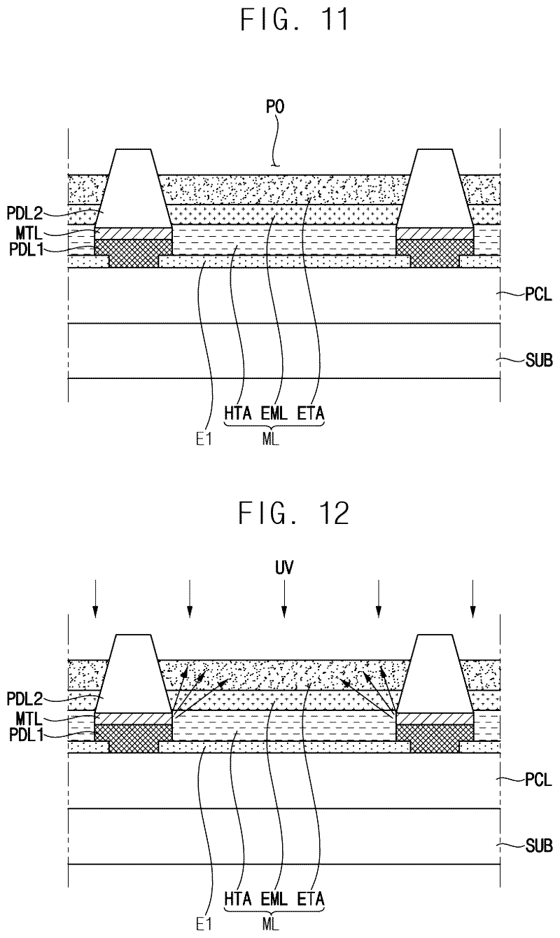

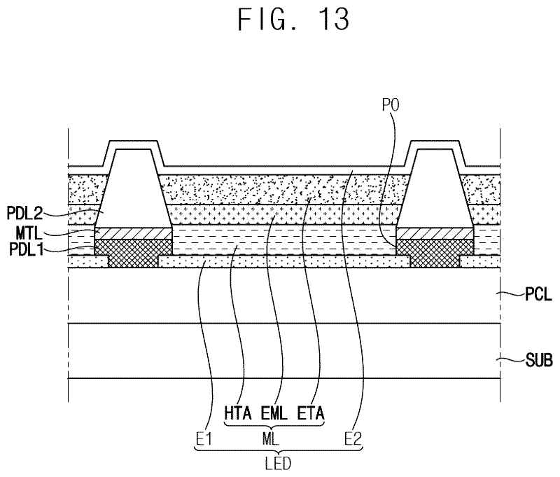

Therefore, during the manufacturing process of the display device DD, a process of modifying a surface of the metal oxide layer may be required to control the oxygen vacancy of the metal oxide layer. According to embodiments, the surface of the metal oxide layer may be modified by radiating ultraviolet rays to the metal oxide layer. For example, the oxygen vacancy of the metal oxide layer may be controlled by radiating ultraviolet rays to the metal oxide layer. This will be described in more detail below with reference to FIG. 12.

The electron transport area ETA may further include a metal-containing material in addition to the materials described above.

The metal-containing material may include at least one of an alkaline metal complex and an alkaline earth metal complex. Metal ions of the alkaline metal complex may be selected from Li ions, Na ions, K ions, Rb ions, and Cs ions, and metal ions of the alkaline earth metal complex may be selected from Be ions, Mg ions, Ca ions, Sr ions, and Ba ions. Ligands coordinated to the metal ions of the alkaline metal complex and the alkaline earth metal complex may be, independently of each other, selected from hydroxyquinoline, hydroxyisoquinoline, hydroxybenzoquinoline, hydroxyacridine, hydroxyphenanthridine, hydroxyphenyloxazole, hydroxyphenylthiazole, hydroxydiphenyloxadiazole, hydroxydiphenylthiadiazole, hydroxyphenylpyridine, hydroxyphenylbenzoimidazole, hydroxyphenylbenzothiazole, bipyridine, phenanthroline, cyclopentadiene, or the like, but are not limited thereto.

The second electrode E2 may be disposed on the intermediate layer ML. The second electrode E2 may include a conductive material such as a metal, alloy, conductive metal nitride, conductive metal oxide, transparent conductive material, or the like. In an embodiment, the second electrode E2 may continuously extend across the pixel areas PXA. As a result, the light emitting element LED may emit the light.

Although not illustrated, an encapsulation member may be additionally disposed on the light emitting element LED. The encapsulation member may protect the light emitting clement LED from external moisture, heat, shock, or the like.

In an embodiment, the encapsulation member may be a glass substrate. The encapsulation member may be bonded to the substrate SUB through a sealing member or the like, and may be spaced apart from the light emitting clement LED in the third direction DR3. A space between the encapsulation member and the light emitting element LED may be filled with air or a filler.

In an embodiment, the encapsulation member may have a structure in which encapsulation layers on the second electrode E2 are stacked. For example, the encapsulation member may include a first inorganic encapsulation layer disposed on the second electrode E2, an organic encapsulation layer disposed on the first inorganic encapsulation layer, and a second inorganic encapsulation layer disposed on the organic encapsulation layer.

According to embodiments, the display device DD may include the first pixel defining layer PDL1 covering at least a portion of the first electrode E1 of the light emitting clement LED, the reflective film MTL on the first pixel defining layer PDL1, and the second pixel defining layer PDL2 on the reflective film MTL. For example, in the display device DD according to embodiments, the structure in which the first pixel defining layer PDL1, the reflective film MTL, and the second pixel defining layer PDL2 are sequentially stacked may define the pixel opening PO which exposes the upper surface of the first electrode E1 of the light emitting element LED.

In the process of curing the emission layer EML formed in the pixel opening PO with ultraviolet rays, at least some of the ultraviolet rays which are radiated may be reflected by the reflective film MTL and reach the emission layer EML. For example, in addition to the ultraviolet rays that directly reach the emission layer EML, the ultraviolet rays reflected by the reflective film MTL may additionally reach the emission layer EML. Accordingly, an amount of the ultraviolet rays reaching the emission layer EML may increase, and a degree of film curing of the emission layer EML by ultraviolet curing may increase. Accordingly, a phenomenon in which a material included in the emission layer EML and a material included in the metal oxide layer are mixed at the interface between the emission layer EML and the metal oxide layer may be reduced or prevented. Accordingly, element characteristics of the light emitting element LED may be improved.

In the process of modifying the surface of the metal oxide layer by radiating ultraviolet rays to the metal oxide layer formed in the pixel opening PO, at least some of the ultraviolet rays which are radiated may be reflected by the reflective film MTL and reach the metal oxide layer. For example, in addition to the ultraviolet rays that directly reach the metal oxide layer, the ultraviolet rays reflected by the reflective film MTL may additionally reach the metal oxide layer. Accordingly, an amount of the ultraviolet rays reaching the metal oxide layer may increase, and a surface modification effect of the metal oxide layer by ultraviolet radiation may increase. For example, the oxygen vacancy of the metal oxide layer may be more easily controlled. Accordingly, element characteristics of the light emitting element LED may be improved.

As the first pixel defining layer PDL1 is disposed below the reflective film MTL, the reflective film MTL and the first electrode E1 may be electrically insulated from each other. Therefore, the reflective film MTL may not affect electrical characteristics of the light emitting element LED. At the same time, as the second pixel defining layer PDL2 is disposed on the reflective film MTL, in the process of forming the intermediate layer ML, a phenomenon in which materials discharged into a pixel opening through inkjet printing overflow toward other pixel openings around the pixel opening may be reduced or prevented. Accordingly, the intermediate layer ML may be more easily formed without substantially deteriorating element characteristics of the light emitting element LED.

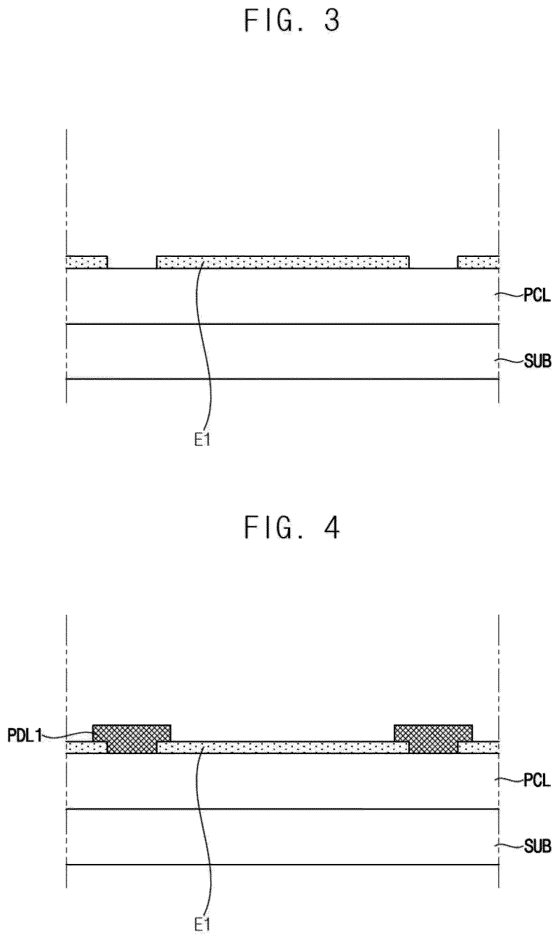

FIGS. 3 to 13 are schematic cross-sectional views illustrating a method of manufacturing a display device according to an embodiment of the disclosure.

Specifically, FIGS. 3 to 13 are schematic cross-sectional views for explaining the manufacturing method of the display device described with reference to FIG. 2. Hereinafter, a description of components of the display device DD may be substantially the same as the description with reference to FIGS. 1 and 2. Accordingly, if detailed descriptions of the components are omitted or simplified, it can be interpreted as being substantially the same as corresponding components described in detail with reference to FIGS. 1 and 2.

For convenience of description, illustrations of components included in the pixel circuit layer PCL are omitted, and may be substantially the same as the illustrations of FIG. 2.

Referring to FIG. 3, the pixel circuit layer PCL may be formed on the substrate SUB. The pixel circuit layer PCL may be formed by applying one or more insulating layers and one or more conductive layers on the substrate SUB and performing a process of patterning each of the insulating layers and the conductive layers multiple times.

The first electrode E1 may be formed on the pixel circuit layer PCL. The first electrode E1 may be formed through a process of applying a conductive layer on the pixel circuit layer PCL and patterning the conductive layer.

Referring to FIG. 4, the first pixel defining layer PDL1 may be formed on the pixel circuit layer PCL and the first electrode E1. The first pixel defining layer PDL1 may be formed through a process of applying an insulating layer on the pixel circuit layer PCL and the first electrode E1 and patterning the insulating layer. The first pixel defining layer PDL1 may be formed to cover at least a portion of the first electrode E1 and expose the upper surface of the first electrode E1. For example, the first pixel defining layer PDL1 may be formed to have a grid shape in a plan view. In an embodiment, the first pixel defining layer PDL1 may be formed of an organic material.

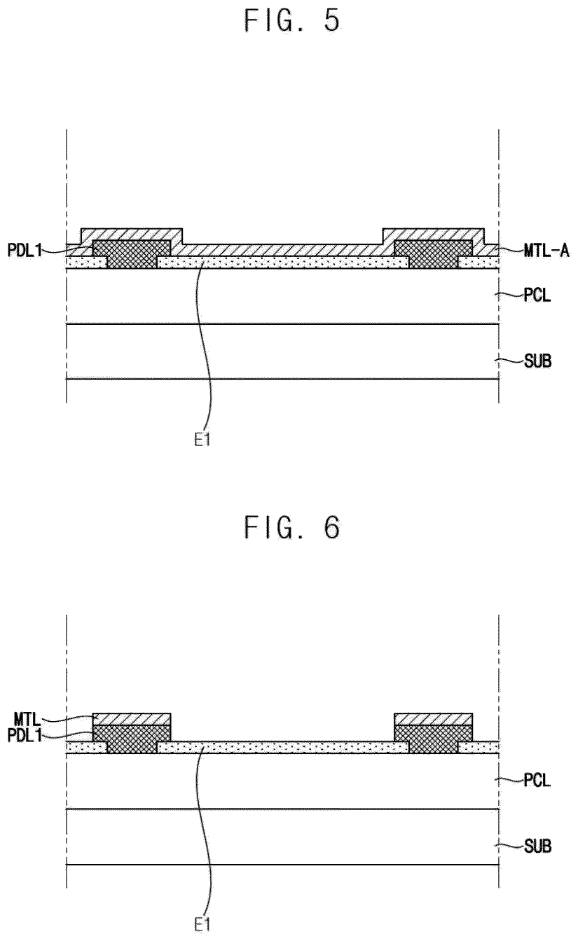

Referring to FIGS. 5 and 6, the reflective film MTL may be formed on the first pixel defining layer PDL1. As illustrated in FIG. 5, a preliminary reflective film MTL-A may be formed on the first electrode E1 and the first pixel defining layer PDL1. The preliminary reflective film MTL-A may be formed of a metal material. For example, the preliminary reflective film MTL-A may be formed by applying the metal material on the first electrode E1 and the first pixel defining layer PDL1 by a spin coat method, a casting method, a micro gravure coat method, a gravure coat method, a bar coat method, a roll coat method. a wire bar coat method, a dip coat method, a spray coat method, or the like. However, the disclosure is not limited thereto.

The metal material that can be used as the preliminary reflective film MTL-A may have a low resistance and a high reflectivity. For example, the preliminary reflective film MTL-A may be formed of aluminum (Al) or an aluminum alloy. The aluminum alloy may include metals such as nickel (Ni), lanthanum (La), titanium (Ti), molybdenum (Mo), or the like, but the disclosure is not limited thereto.

As illustrated in FIG. 6, the preliminary reflective film MTL-A may be patterned to form the reflective film MTL. For example, the reflective film MTL may be formed by removing other portions of the preliminary reflective film MTL-A except for portions that overlaps the first pixel defining layer PDL1 in a plan view. For example, the reflective film MTL may be formed to have a grid shape in a plan view.

In an embodiment, a process of patterning the preliminary reflective film MTL-A may be performed through an etching process, exposure and development processes, or the like. The process of patterning the preliminary reflective film MTL-A may be performed through a dry etching process using an etching gas.

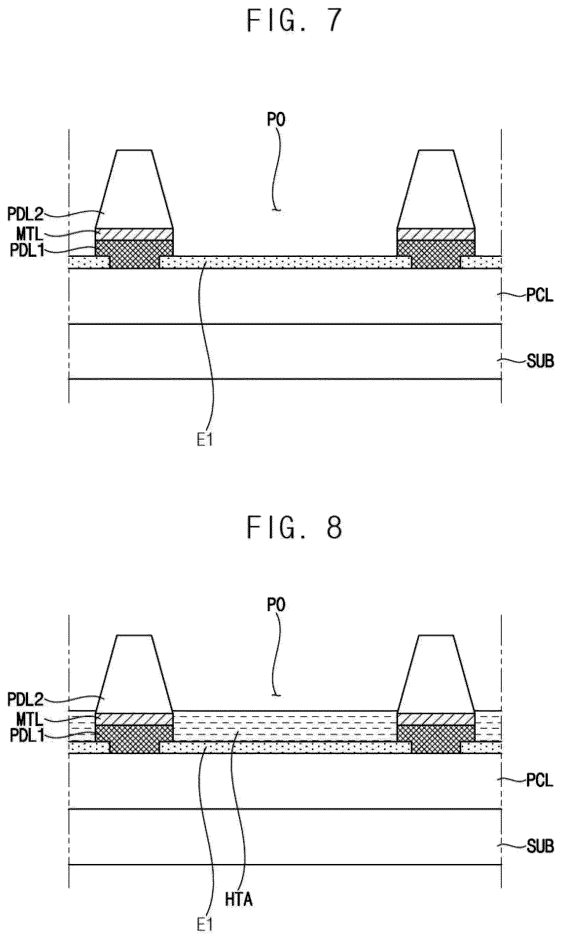

Referring to FIG. 7, the second pixel defining layer PDL2 may be formed on the reflective film MTL. The second pixel defining layer PDL2 may be formed through a process of applying an insulating layer on the first electrode E1, the first pixel defining layer PDL1, and the reflective film MTL and patterning the insulating layer. For example, the second pixel defining layer PDL2 may be formed to have a grid shape in a plan view. In an embodiment, the second pixel defining layer PDL2 may be formed of an organic material.

The structure in which the first pixel defining layer PDL1, the reflective film MTL, and the second pixel defining layer PDL2 are sequentially stacked may be formed on the pixel circuit layer PCL. The structure may define the pixel opening PO which exposes the upper surface of the first electrode E1. For example, the structure in which the first pixel defining layer PDL1, the reflective film MTL, and the second pixel defining layer PDL2 are sequentially stacked may be formed to have a grid shape in a plan view.

Referring to FIG. 8, the hole transport area HTA may be formed on the first electrode E1 exposed by the pixel opening PO. In an embodiment, the hole transport area HTA may be formed through inkjet printing. For example, an organic composition may be provided through inkjet printing in the pixel opening PO. The organic composition may be a material for forming the hole transport area HTA. Thereafter, the organic composition may be dried to form the hole transport area HTA.

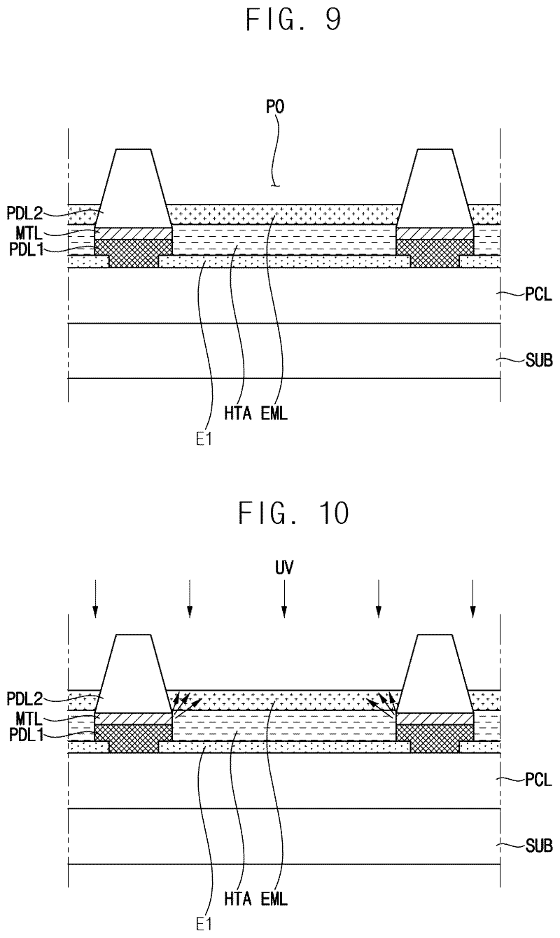

Referring to FIG. 9, the emission layer EML may be formed on the hole transport area HTA in the pixel opening PO. In an embodiment, the emission layer EML may be formed through inkjet printing. For example, the composition for forming the emission layer EML may be provided through inkjet printing on the hole transport area HTA in the pixel opening PO. The composition for forming the emission layer EML may include the solvent, the quantum dot, and the cross-linking agent activated by ultraviolet rays. The composition for forming the emission layer EML may be dried to form the emission layer EML.

Referring to FIG. 10, the emission layer EML may be cured with ultraviolet rays UV. As the emission layer EML includes the cross-linking agent activated by ultraviolet rays, in case that the emission layer EML is radiated with the ultraviolet rays UV, film curing of the emission layer EML may occur. Accordingly, a phenomenon of mixing materials of the metal oxide layer formed on the emission layer EML in a subsequent process with materials of the emission layer EML may be reduced or prevented.

In an embodiment, in the process of curing the emission layer EML with the ultraviolet rays UV, at least some of the ultraviolet rays UV which are radiated may be reflected by the reflective film MTL and reach the emission layer EML. For example, in addition to the ultraviolet rays UV that directly reach the emission layer EML, the ultraviolet rays UV reflected by the reflective film MTL may additionally reach the emission layer EML. Accordingly, an amount of the ultraviolet rays UV reaching the emission layer EML may increase, and a degree of film curing of the emission layer EML may increase.

In an embodiment, the emission layer EML may be cured with the ultraviolet rays UV at a temperature of less than about 180° C., e.g., equal to or less than about 140° C. If the temperature for performing a curing process using the ultraviolet rays UV is equal to or more than about 180° C., the quantum dot may be damaged and element characteristics of the light emitting element LED (see FIG. 2) may deteriorate.

According to embodiments, a separate heat curing process may be omitted by curing the emission layer EML with the ultraviolet rays UV. Since a heat curing process needs to be performed at a high temperature of equal to or more than about 180° C., element characteristics of the emission layer EML may deteriorate. Therefore, according to embodiments, by omitting the heat curing process, film curing of the emission layer EML may be performed without substantially deteriorating element characteristics of the emission layer EML. An amount of the ultraviolet rays UV reaching the emission layer EML may be increased by the reflective film MTL, and a degree of film curing of the emission layer EML may increase.

Referring to FIG. 11, the electron transport area ETA may be formed on the emission layer EML in the pixel opening PO. In an embodiment, the electron transport area ETA may be formed through inkjet printing. As a result, the intermediate layer ML including the hole transport area HTA, the emission layer EML, and the electron transport area ETA may be formed in the pixel opening PO.

Specifically, in a structure light emitting element in which the electron transport area ETA is disposed on the emission layer EML, the electron transport area ETA may include the metal oxide layer, and the metal oxide layer may be the lowest layer of the electron transport area ETA. Accordingly, the metal oxide layer may be formed adjacent to the emission layer EML in the pixel opening PO.

Hereinafter, for convenience of description, a method of forming the metal oxide layer will be described in more detail, taking as an example a case where the electron transport area ETA illustrated in FIG. 11 has a single-layer structure of the metal oxide layer.

In an embodiment, the metal oxide layer may be formed through inkjet printing. For example, a composition for forming the metal oxide layer may be provided on the emission layer EML in the pixel opening PO through inkjet printing. The composition for forming the metal oxide layer may include a solvent and a metal oxide. Thereafter, the composition for forming the metal oxide layer may be dried to form the metal oxide layer.

Referring to FIG. 12, the ultraviolet rays UV may be radiated to the metal oxide layer. By radiating the ultraviolet rays UV to the metal oxide layer, the surface of the metal oxide layer may be modified. For example, the oxygen vacancy of the metal oxide layer may be controlled by radiating the ultraviolet rays UV to the metal oxide layer. Accordingly, the characteristics of the light emitting element LED (see FIG. 2) may be improved.

In an embodiment, in a process of radiating the ultraviolet rays UV to the metal oxide layer, at least some of the radiated ultraviolet rays UV may be reflected by the reflective film MTL and reach the metal oxide layer. For example, in addition to the ultraviolet rays UV that directly reach the metal oxide layer, the ultraviolet rays UV reflected by the reflective film MTL may additionally reach the metal oxide layer. Accordingly, an amount of the ultraviolet rays UV reaching the metal oxide layer may increase, and the surface modification effect of the metal oxide layer may increase.

In an embodiment, the metal oxide layer may be radiated with the ultraviolet rays UV at a temperature of less than about 180° C., specifically equal to or less than about 140° C. If the temperature for radiating the ultraviolet rays UV is equal to or more than about 180° C., the quantum dot may be damaged and element characteristics of the light emitting clement LED (see FIG. 2) may deteriorate.

According to embodiments, a separate aging process may be omitted by modifying the surface of the metal oxide layer by radiating the ultraviolet rays UV to the metal oxide layer. The aging process may be a process of leaving or heating the display device DD after manufacturing the display device DD so that an aging element such as acid reaches the metal oxide layer. Therefore, for the aging process, a separate coating layer containing acid may be required in the display device DD. The coating layer may have problems in that it is difficult to form a uniform film, causing stains in the display area DA (see FIG. 1) and making it difficult to store for a long time. Therefore, according to embodiments, by omitting the aging process, surface modification of the metal oxide layer may be performed without substantially deteriorating a display quality of the display device DD. Additionally, an amount of the ultraviolet rays UV reaching the metal oxide layer may be increased by the reflective film MTL, and the surface modification effect of the metal oxide layer may increase.

Referring to FIG. 13, the second electrode E2 may be formed on the second pixel defining layer PDL2 and the intermediate layer ML. Accordingly, the light emitting element LED that includes the first electrode E1, the intermediate layer ML, and the second electrode E2 and is a quantum dot light emitting element may be formed.

Thereafter, although not illustrated, the encapsulation member may be additionally formed on the second electrode E2. In an embodiment, the encapsulation member may be bonded to the substrate SUB through the sealing member or the like. However, the disclosure is not limited thereto.

FIGS. 14 to 17 are schematic cross-sectional views illustrating various embodiments taken along line I-I′ of FIG. 1. Specifically, FIGS. 14 to 17 may correspond to the schematic cross-sectional view of FIG. 2.

In the embodiments of the display device DD described with reference to FIGS. 14 to 17, if detailed descriptions of components that overlap those of an embodiment of the display device DD described with reference to FIG. 2 are or simplified, it can be interpreted as being substantially the same as corresponding components described in detail with reference to FIGS. 1 and 2.

Referring to FIG. 14, in an embodiment, the second pixel defining layer PDL2 may expose at least a portion of the upper surface of the reflective film MTL. For example, the second pixel defining layer PDL2 may expose sides of the upper surface of the reflective film MTL. However, the disclosure is not limited thereto. The second pixel defining layer PDL2 may expose at least a portion of the upper surface of the reflective film MTL, thereby increasing a reflectance of the reflective film MTL with respect to the ultraviolet rays which are radiated. Accordingly, an amount of the ultraviolet rays reflected by the reflective film MTL and reaching the emission layer EML or the metal oxide layer may further increase. Accordingly, element characteristics of the light emitting element LED may be further improved.

A manufacturing method of the display device DD described with reference to FIG. 14 may be distinguishable from the manufacturing method of the display device described with reference to FIGS. 3 to 13 at least in that the second pixel defining layer PDL2 is formed to expose a portion of the upper surface of the reflective film MTL in the forming of the second pixel defining layer PDL2 (see FIG. 7).

Referring to FIG. 15, in an embodiment, the second pixel defining layer PDL2 may include a light blocking material. Examples of light blocking materials that can be used as the second pixel defining layer PDL2 may include black dye, black pigment, carbon black, or the like. These can be used alone or in combination with each other. Since the second pixel defining layer PDL2 includes the light blocking material, a visibility of external light (e.g., visible light) caused by the reflective film MTL may be reduced. Accordingly, deterioration of a display quality of the display device DD due to the external light being visible may be reduced or prevented.

A manufacturing method of the display device DD described with reference to FIG. 14 may be distinguishable from the manufacturing method of the display device described with reference to FIGS. 3 to 13 at least in that the second pixel defining layer PDL2 is formed by applying an insulating layer that further includes a light blocking material in addition to an organic material and patterning the insulating layer in the forming of the second pixel defining layer PDL2 (sec FIG. 7).

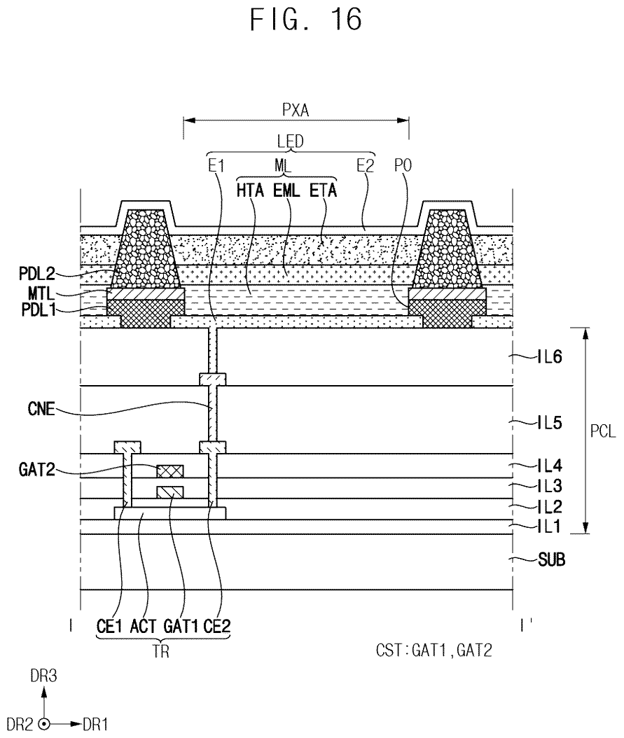

Referring to FIG. 16, as in the embodiment in which the second pixel defining layer PDL2 includes the light blocking material, the second pixel defining layer PDL2 may expose at least a portion of the upper surface of the reflective film MTL. Accordingly, a reflectance of the reflective film MTL with respect to the ultraviolet rays which are radiated may be further increased without substantially deteriorating a display quality of the display device DD due to the external light being visible.

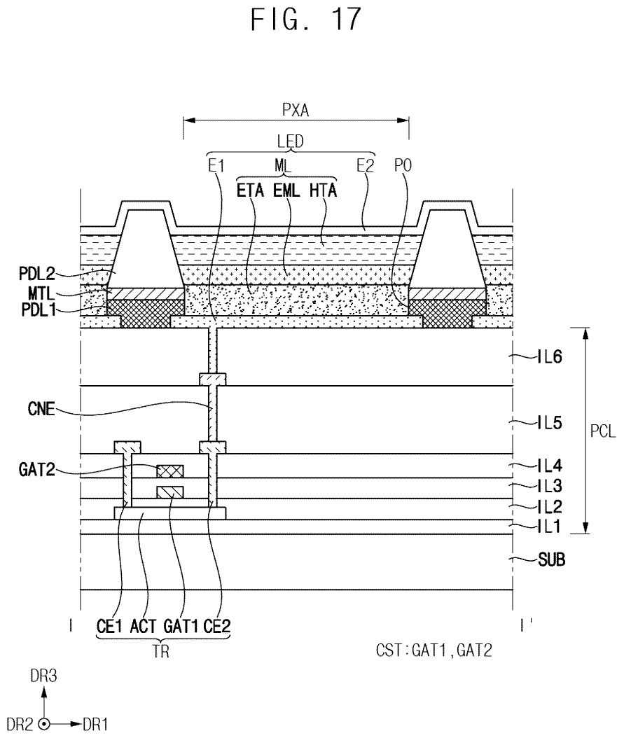

Referring to FIG. 17, in an embodiment, the electron transport area ETA, the emission layer EML, and the hole transport area HTA may be sequentially stacked on the first electrode E1. The light emitting element LED may be an inverted-structure light emitting element in which the first electrode E1 is a cathode and the second electrode E2 is an anode.

As described above, the electron transport area ETA may include the metal oxide layer. For example, in an inverted-structure light emitting element in which the electron transport area ETA is disposed below the emission layer EML, the metal oxide layer may be the uppermost layer of the electron transport area ETA. In other words, the metal oxide layer may be disposed below the emission layer EML so as to directly contact the emission layer EML.

In an embodiment, the metal oxide layer may include a light-reactive material. For example, the metal oxide layer may include a photo-crosslinking agent. Specifically, the metal oxide layer may further include a cross-linking agent activated by ultraviolet rays.

Examples of the cross-linking agent that can be included in the metal oxide layer may include a crosslinkable monomer having an ethylenically unsaturated group, a urethane monomer, or the like. Examples of the crosslinkable monomer having an ethylenically unsaturated group may include 1,4-butanediol diacrylate, 1,3-butylene glycol diacrylate, ethylene glycol diacrylate, pentaerythritol tetraacrylate, tricthylene glycol diacrylate, polyethylene glycol diacrylate, dipentaerythritol diacrylate, sorbitol triacrylate, bisphenol A diacrylate derivative, trimethylpropane triacrylate, dipentaerythritol polyacrylate, dipentaerythritol hexaacrylate, or the like. These can be used alone or in combination with each other. The urethane monomer may be a general cross-linking monomer having a urethane structure, and its type is not particularly limited.

As the metal oxide layer includes the cross-linking agent activated by ultraviolet rays, film curing of the metal oxide layer may occur in case that radiating ultraviolet rays to the metal oxide layer. A phenomenon of mixing materials of the emission layer formed on the metal oxide layer in a subsequent process with materials of the metal oxide layer may be reduced or prevented.

For example, in a process of forming an inverted-structure light emitting element, surface modification of the metal oxide layer and film curing of the metal oxide layer may be performed simultaneously by radiating ultraviolet rays to the metal oxide layer. Accordingly, the characteristics of the light emitting element LED may be further improved, and a manufacturing process of the display device DD may be simplified.

A manufacturing method of the display device DD described with reference to FIG. 17 may be distinguishable from the manufacturing method of the display device described with reference to FIGS. 3 to 13 at least in that an order of the forming of the hole transport area HTA (see FIG. 8) and the forming of the electron transport area ETA and the radiating of the ultraviolet rays to the electron transport area ETA (see FIGS. 11 and 12) is changed.

Although not illustrated, even in the embodiment in which the light emitting element LED has the inverted structure, the second pixel defining layer PDL2 may expose at least a portion of the upper surface of the reflective film MTL as illustrated in FIG. 14. The second pixel defining layer PDL2 may further include the light blocking material as illustrated in FIG. 15. The second pixel defining layer PDL2 may further include the light blocking material and expose at least a portion of the upper surface of the reflective film MTL as illustrated in FIG. 16. A detailed description will be omitted since it overlaps the description referring to FIGS. 14 to 16.

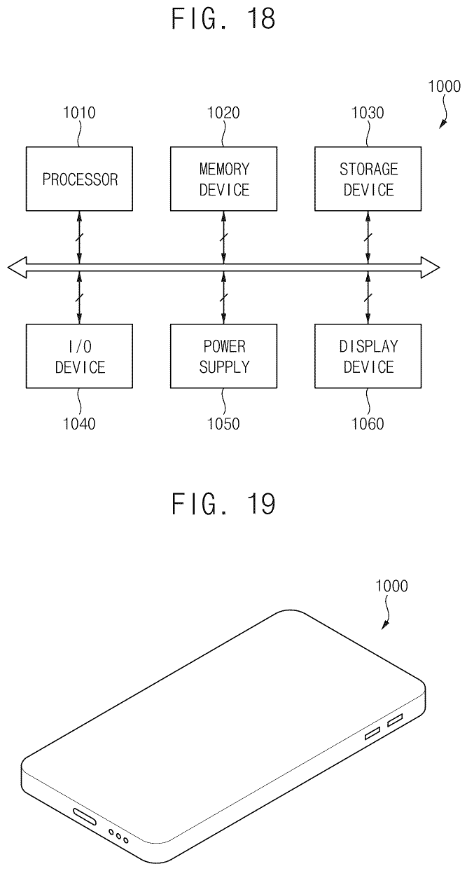

FIG. 18 is a block diagram illustrating an electronic device 1000. FIG. 19 is a view illustrating an example in which the electronic device of FIG. 18 is implemented as a smart phone.

Referring to FIGS. 18 and 19, the electronic device 1000 may include a processor 1010, a memory device 1020, a storage device 1030, an input/output (I/O) device 1040, a power supply 1050, and a display device 1060. The display device 1060 may be the display device DD of FIG. 1. In addition, the electronic device 1000 may further include a plurality of ports for communicating with a video card, a sound card, a memory card, a universal serial bus (USB) device, other systems, or the like.

In an embodiment, as illustrated in FIG. 19, the electronic device 1000 may be implemented as the smart phone. However, the electronic device 1000 is not limited thereto. For example, the electronic device 1000 may be implemented as a cellular phone, a video phone, a smart pad, a smart watch, a tablet PC, a car navigation system, a computer monitor, a laptop, a head mounted display (HMD) device, or the like.

The processor 1010 may perform various computing functions. The processor 1010 may be a microprocessor, a central processing unit (CPU), an application processor (AP), or the like. The processor 1010 may be coupled to other components through an address bus, a control bus, a data bus, or the like. In an embodiment, the processor 1010 may be coupled to an extended bus such as a peripheral component interconnection (PCI) bus.

The memory device 1020 may store data for operations of the electronic device 1000. For example, the memory device 1020 may include at least one non-volatile memory device such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, a ferroelectric random access memory (FRAM) device, or the like and/or at least one volatile memory device such as a dynamic random access memory (DRAM) device, a static random access memory (SRAM) device, a mobile DRAM device, or the like.

The storage device 1030 may include a solid-state drive (SSD) device, a hard disk drive (HDD) device, a CD-ROM device, or the like. The I/O device 1040 may include an input device such as a keyboard, a keypad, a mouse device, a touch-pad, a touch-screen, or the like, and an output device such as a printer, a speaker, or the like. In an embodiment, the I/O device 1040 may include the display device 1060.

The I/O device 1040 may include an input device such as a keyboard, a keypad, a mouse device, a touch-pad, a touch-screen, and the like, and an output device such as a printer, a speaker, and the like. In an embodiment, the I/O device 1040 may include the display device 1060.

The power supply 1050 may provide power for operations of the electronic device 1000. The display device 1060 may be connected to other components through buses or other communication links.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first electrode;
a second electrode on the first electrode and facing the first electrode;
an intermediate layer between the first electrode and the second electrode and including an emission layer including a quantum dot;
a first pixel defining layer which covers at least a portion of the first electrode and exposes an upper surface of the first electrode;
a reflective film on the first pixel defining layer; and
a second pixel defining layer on the reflective film.

2. The display device of claim 1, wherein the reflective film includes a metal material.

3. The display device of claim 2, wherein the reflective film includes aluminum or an aluminum alloy.

4. The display device of claim 1, wherein the reflective film is electrically disconnected from the first electrode.

5. The display device of claim 1, wherein the emission layer further includes a cross-linking agent activated by ultraviolet rays.

6. The display device of claim 1, wherein
a structure in which the first pixel defining layer, the reflective film, and the second pixel defining layer are sequentially stacked defines a pixel opening exposing the upper surface of the first electrode, and
the intermediate layer is disposed in the pixel opening.

7. The display device of claim 1, wherein a structure in which the first pixel defining layer, the reflective film, and the second pixel defining layer are sequentially stacked surrounds the intermediate layer in a plan view.

8. The display device of claim 1, wherein the intermediate layer further includes a metal oxide layer adjacent to the emission layer and including metal oxide.

9. The display device of claim 1, wherein the reflective film directly contacts the intermediate layer.

10. The display device of claim 1, wherein at least a portion of the reflective film is exposed from the second pixel defining layer.

11. The display device of claim 1, wherein the second pixel defining layer includes a light blocking material.

12. A method of manufacturing a display device, the method comprising:
forming a first pixel defining layer which covers at least a portion of a first electrode and exposes an upper surface of the first electrode;
forming a reflective film on the first pixel defining layer;
forming a second pixel defining layer on the reflective film;
forming an emission layer including a quantum dot on the first electrode; and
curing the emission layer with ultraviolet rays.

13. The method of claim 12, wherein the emission layer further includes a cross-linking agent activated by the ultraviolet rays.

14. The method of claim 12, wherein in the curing of the emission layer with the ultraviolet rays,
at least some of the ultraviolet rays are reflected by the reflective film and reach the emission layer.

15. The method of claim 12, wherein the curing of the emission layer with the ultraviolet rays is performed at a temperature of less than about 180° C.

16. The method of claim 12, wherein the forming of the reflective film includes:
forming a preliminary reflective film including a metal material on the first electrode and the first pixel defining layer; and
patterning the preliminary reflective film.

17. The method of claim 16, wherein the preliminary reflective film includes aluminum or an aluminum alloy.

18. The method of claim 12, further comprising:
forming a metal oxide layer including metal oxide on the first electrode; and
radiating ultraviolet rays to the metal oxide layer.

19. The method of claim 18, wherein in the radiating of the ultraviolet rays to the metal oxide layer,
at least some of the ultraviolet rays are reflected by the reflective film and reach the metal oxide layer.

20. The method of claim 18, wherein the emission layer and the metal oxide layer are formed adjacent to each other.

21. An electronic device comprising:
a display device; and
a power supply which provides power to the display device,
wherein the display device includes:
a first electrode;
a second electrode on the first electrode and facing the first electrode;
an intermediate layer between the first electrode and the second electrode and including an emission layer including a quantum dot;
a first pixel defining layer which covers at least a portion of the first electrode and exposes an upper surface of the first electrode;
a reflective film on the first pixel defining layer, and
a second pixel defining layer on the reflective film.
